(19) United States
(12) Patent Application Publication
(10) Pub. No.: US 2016/0075554 A1
(43) Pub. Date: Mar. 17, 2016

(54) INTERNAL BARRIER FOR ENCLOSED MEMS DEVICES

(71) Applicant: InvenSense, Inc., San Jose, CA (US)

(72) Inventors: Anatole HUANG, Sunnyvale, CA (US); Jongwoo SHIN, Pleasanton, CA (US); Peter SMEYS, San Jose, CA (US); Cerina ZHANG, Milpitas, CA (US); Jong Il SHIN, San Jose, CA (US)

(21) Appl. No.: 14/850,860

(22) Filed: Sep. 10, 2015

Related U.S. Application Data
(60) Provisional application No. 62/049,005, filed on Sep. 11, 2014.

(51) Int. Cl. B81B 7/00; B81C 1/00

(52) U.S. Cl. CPC B81B 7/0061; B81C 1/00309; B81B 2203/0353; B81B 2207/012; B81B 2207/07; B81C 2201/013; B81C 2203/0785; B81C 2203/0172

(57) ABSTRACT

A MEMS device having a channel configured to avoid particle contamination is disclosed. The MEMS device includes a MEMS substrate and a base substrate. The MEMS substrate includes a MEMS device area, a seal ring and a channel. The seal ring provides for dividing the MEMS device area into a plurality of cavities, wherein at least one of the plurality of cavities includes one or more vent holes. The channel is configured between the one or more vent holes and the MEMS device area. Preferably, the channel is configured to minimize particles entering the MEMS device area directly. The base substrate is coupled to the MEMS device substrate.

### CROSS-REFERENCE TO RELATED APPLICATION

This application claims benefit under 35 USC 119(e) of U.S. Provisional Patent Application No. 62/049,005, filed on Sep. 11, 2014, entitled “INTERNAL BARRIER FOR ENCLOSED MEMS DEVICES,” which is incorporated herein by reference in its entirety.

### FIELD OF THE INVENTION

The present invention relates generally to Microelectromechanical systems (MEMS) structures and more particularly to providing a MEMS structure which provides an internal barrier.

### BACKGROUND

MEMS devices that include MEMS and complementary metal-oxide semiconductors (CMOS) contact surfaces that are conductive. Typically the MEMS devices also include an actuator layer therewithin. It is desirable to improve on processes that are utilized to provide such devices. It is also desirable to provide for an improved venting configuration in MEMS devices which may also provide for different pressures across multiple sensors in a MEMS device. Therefore, there is a strong need for a solution that overcomes the aforementioned issues. The present invention addresses such a need.

### SUMMARY

A MEMS device having a channel configured to avoid particle contamination is disclosed. The MEMS device includes a MEMS substrate and a base substrate. The MEMS substrate includes a MEMS device area, a seal ring and a channel. The seal ring provides for dividing the MEMS device area into a plurality of cavities, wherein at least one of the plurality of cavities includes one or more vent holes. The channel is configured between the one or more vent holes and the MEMS device area. Preferably, the channel is configured to minimize particles entering the MEMS device area directly. The base substrate is coupled to the MEMS device substrate.

A method for manufacturing a MEMS device having a non-linear channel between one or more vent holes and a MEMS device area is disclosed. The method of manufacture includes manufacturing a MEMS device substrate having a first conductive pad coupled via a eutectic bond to a second conductive pad on a CMOS substrate. The method also provides that the MEMS device substrate includes: a MEMS device area; a seal ring for dividing the MEMS device area into a plurality of cavities; and a channel having a non-linear pathway between the one or more vent holes and the MEMS device area. More specifically, the method disclosed provides for a channel configuration which minimizes particles entering the MEMS device area directly to reduce the likelihood of failure of the resident devices. The method also provides for etching the one or more vent holes to be configured with at least one of the plurality of cavities and etching the non-linear pathway of the channel.

### BRIEF DESCRIPTION OF THE DRAWINGS

FIG. 1 is a diagram of a MEMS device in accordance with an embodiment.

FIG. 2 depicts a top-down view of the MEMS device including a barrier in accordance with one or more embodiments of the present invention.

FIGS. 3A and 3B are diagrams that depict a first method for providing a channel through a MEMS device.

FIGS. 4A and 4B are diagrams that depict a second method for providing a channel through a MEMS device.

FIGS. 5A and 5B are diagrams that depict a third method for providing a channel through a MEMS device.

FIG. 6 sets forth a flowchart of the method of manufacture of the present invention in accordance with one or more embodiments.

### DETAILED DESCRIPTION

The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

The present invention relates generally to MEMS structures and more particularly to providing a MEMS structure which provides for improved avoidance of particle contamination to sensors. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

MEMS refer to a class of devices fabricated using semiconductor-like processes and exhibiting mechanical characteristics such as the ability to move or deform. MEMS often, but not always, interact with electrical signals. A MEMS device may refer to a semiconductor device implemented as a microelectromechanical system. A MEMS device includes mechanical elements and optionally includes electronics for sensing. MEMS devices include but are not limited to gyroscopes, accelerometers, magnetometers, and pressure sensors.

In MEMS devices, a port is an opening through a substrate to expose MEMS structure to the surrounding environment. A chip includes at least one substrate typically formed from a semiconductor material. A single chip may be formed from multiple substrates, wherein the substrates are mechanically bonded to preserve functionality. Multiple chips include at least two substrates, wherein the at least two substrates are electrically connected but do not require mechanical bonding.

Typically, multiple chips are formed by dicing wafers. MEMS wafers are silicon wafers that contain MEMS structures. MEMS structures may refer to any feature that may be part of a larger MEMS device. One or more MEMS features comprising moveable elements is a MEMS structure. MEMS features may refer to elements formed by a MEMS fabrication process such as bump stop, damping hole, via, port, plate, proof mass, standoff, spring, and seal ring.

MEMS substrates provide mechanical support for the MEMS structure. The MEMS structural layer is attached to the MEMS substrate. The MEMS substrate is also referred to as handle substrate or handle wafer. In some embodiments, the handle substrate serves as a cap to the MEMS structure. Bonding may refer to methods of attaching and the MEMS substrate and an integrated circuit (IC) substrate may be bonded using a eutectic bond (e.g., AlGe, CuSn, AuSi), fusion bond, compression, thermocompression, adhesive bond (e.g., glue, solder, anodic bonding, glass frit). An IC substrate may refer to a silicon substrate with electrical circuits, typically CMOS circuits. A package provides electrical connection between bond pads on the chip to a metal lead that can be soldered to a printed board circuit (PCB). A package typically comprises a substrate and a cover.

In a further embodiment, the MEMS device includes a standoff layer comprising a plurality of nanowire anchored to the MEMS substrate; the term standoff, as used herein, generally refers to a condition and/or functionality whereby two surfaces that are otherwise being forced together in contact are held back from actual contact which is provided by an outward or repelling force provided by physical contact such as with nanowire, but not exclusively.

In a further preferred embodiment, there is at least one first conductive pad on the MEMS substrate which is coupled to at least one second conductive pad on the CMOS substrate via a eutectic bond. Further, in a preferred embodiment, the MEMS substrate includes at least one standoff thereon with at least a first conductive pad being coupled to the at least one standoff and a channel pathway is vented through at least one standoff included on the MEMS substrate. As used herein the term base substrate may also comprise a CMOS substrate having an electrical circuit.

A system and method in accordance with the present invention provides for vent holes in a handle wafer and configuring a channel in a MEMS device which provides for air flow to a device area and enabling the cavity pressure to different pressures between multiple cavities, while restricting unintended particles and byproducts from entering the device area and possibly causing the MEMS device to fail.

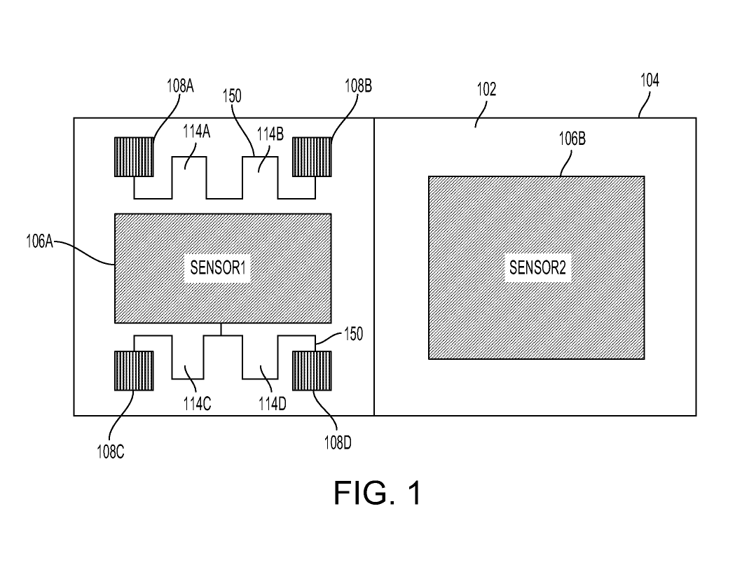

FIG. 1 is a diagram of a MEMS device 100 in accordance with an embodiment. FIG. 1 shows an overview of the MEMS device 100, where a MEMS device area 102 is separated by the seal ring 104 into a first sensor cavity 106a and a second sensor cavity 106b. In an embodiment, the cavities 106a and 106b are hermetically vacuum sealed. In an embodiment, the first sensor cavity 106a, pressure is increased therein by etching vent holes 108a-108d through a handle wafer and then the vent holes 108a-108d are sealed, preferably with a polymer. In an embodiment first sensor cavity 106a cavity may have a pressure of approximately 1 atmosphere. In order to prevent 1) the plasma during vent hole etch process and 2) the polymer during patterning contaminating the devices in the first sensor cavity 106a, barrier between the vent holes 108a-108d and MEMS devices located in the first sensor cavity 106a to prevent any byproducts entering device area directly, only a small gap is opened to allow the pressure to equalize. For exemplary purposes, there are four vent holes depicted (108a-108d) within the first sensor cavity 106a, though the present invention is not so limited. As above described, the vent holes 108a-108d are provided for the first sensor cavity 106a to provide for increased pressure.

In an embodiment, the one or more vent holes 108a-108d are achieved by etching through a handle wafer and then sealing the one or more vent holes 108a-108d with a polymer upon completion of the MEMS device to create a predetermined pressure for the first cavity 106a. In a further embodiment, the pressure created in the first sensor is at a predetermined pressure such that when the vent holes 108a-108d are sealed, the device area 104 is then sealed at a predetermined pressure. In one or more embodiments, the device area of sensor cavity 106a and the device area of sensor cavity 106b are sealed separately, where devices in sensor cavity 106a achieves an approximately 1 atmosphere pressure during manufacture when the vent holes 108a-108d are sealed with a polymer, the pressure of the second sensor cavity 106b, may be at a pressure independent of devices in first sensor cavity 106a.

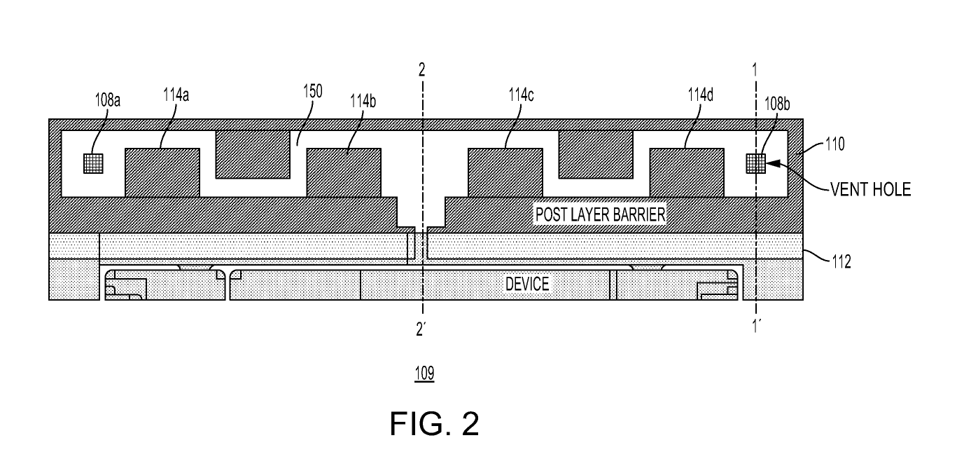

FIG. 2 depicts a top-down view of a MEMS substrate 109 in accordance with one or more embodiments of the present invention. The MEMS substrate 109 includes a MEMS handle wafer 110 coupled to a MEMS device wafer 112. FIG. 2 further depicts one or more barriers 114a-114d, though the present invention is not so limited to the specifics diagrammed in FIG. 1. The one or more barriers 114a-114d are arranged and configured between the vent holes 108a and 108b and the MEMS device wafer 112 to avoid the unintended entrance of particle contaminants or manufacturing byproducts to the MEMS device during processing, including but not limited to those of plasma and polymers which may occur during etching and patterning, respectively, for instance.

In an embodiment, the channel 150 is arranged to provide for a small air gap being configured to enable pressure equalization for the MEMS device area. Barriers 114a-114d are the bend features to act as particle trap and increase the mean-free-path from the vent holes 108a and 108b to the device area to avoid particles from entering. In a further embodiment, vent holes 108a and 108b are arranged with the channel 150 to provide for venting via a configuration creating a particulate trap, thereby avoiding an unobstructed or direct pathway from the air gap of the vent hole to a sensor in the MEMS device area.

Preferably, vent holes 108a-108b are created for the present invention by etching holes through the front side of the handle wafer 110, allowing air to flow into the sensor cavity 106a through channel 150 configured to prevent the entry of unintended particles and byproducts. The channel 150 is preferably created by UCAV etch on the back side of the handle wafer 110, thereby allowing pressure equalization via a vent hole 108 to the MEMS device wafer 112.

It will be appreciated by those skilled in the art that preferably the channels are configured to be indirect and non-linear to the MEMS device area, wherein one or more channels may be configured to be analogous to a series of sequentially arranged line segments having a non-linear construct; similarly, one or more channels may depict a maze-like configuration to thereby increase the mean free path to prevent any unintended particles and byproducts from traversing from the vent hole to the MEMS device. For instance, from FIG. 1, the channel includes a pathway having one or more barriers 114 or turns within the pathway such that the resulting pathway is non-linear as between the device area and the one or more vent holes.

In one or more preferred embodiments, vent holes configured in accordance with the present invention may range in size, with a preferred arrangement of a vent hole ranging approximately from 15 um to 150 um in dimension. Channels configured in accordance with the present invention in one or more preferred embodiments may range in size, with a preferred arrangement of a pathway of a channel having a dimension or width ranging approximately from 1 um to 15 um. A barrier configured in accordance with the present invention in one or more preferred embodiments may range in size, with a preferred arrangement of a barrier having a dimension or width ranging approximately from 20 um and upwards

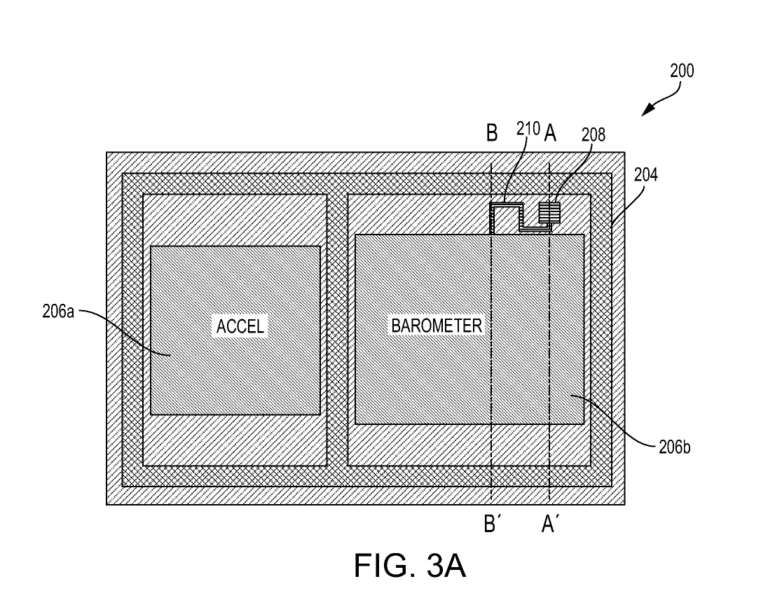

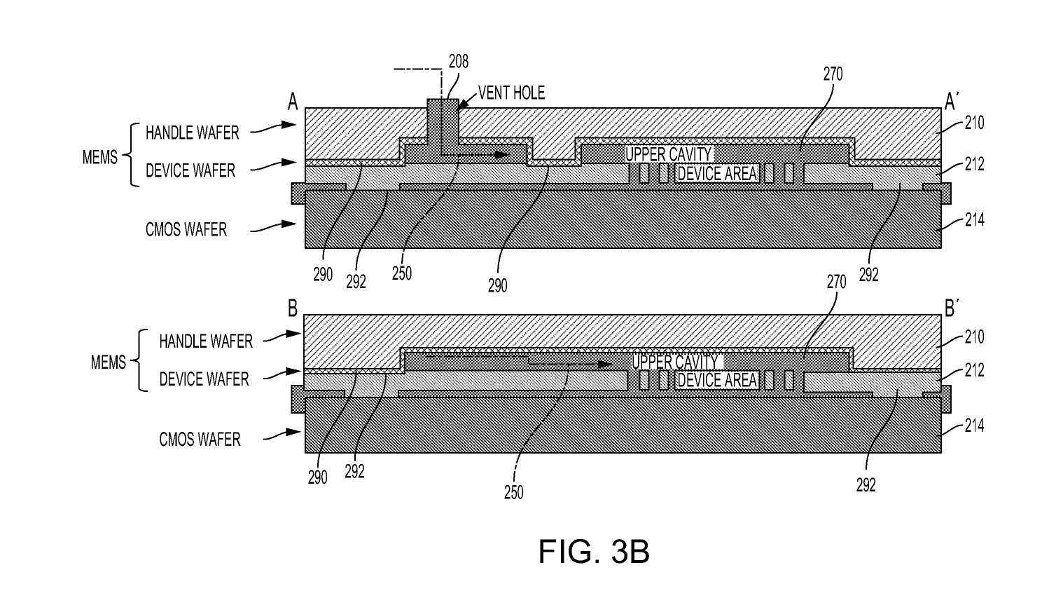

FIGS. 3A and 3B are diagrams that depict a first method for providing a channel through a MEMS device 200. FIG. 3A illustrates a top view of MEMS device 200. FIG. 3B illustrates a side view of the MEMS device 200 which shows a MEMS substrate including handle wafer 210 and device wafer 212 coupled to a CMOS substrate 214 and cross-sections A-A′ and B-B′ shown in FIG. 3A. FIG. 3B illustrates that an opening is provided through handle wafer 210. Referring to the cross section B-B′ the channel 250 is through the upper cavity 270.

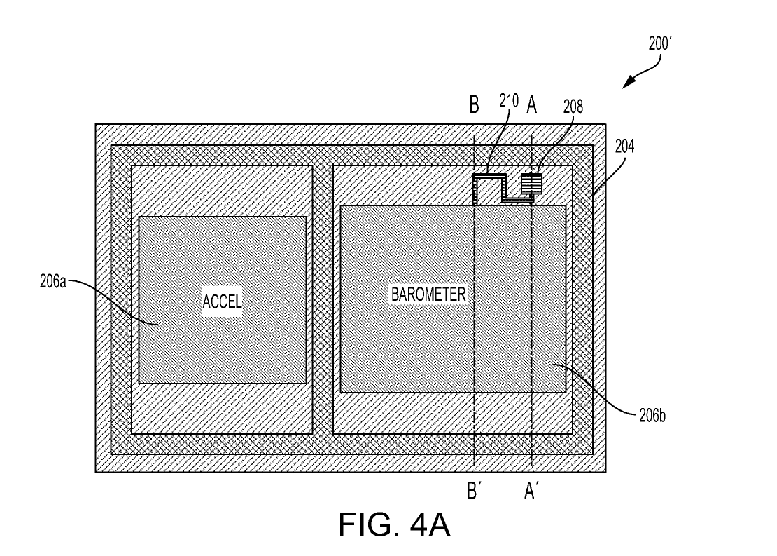

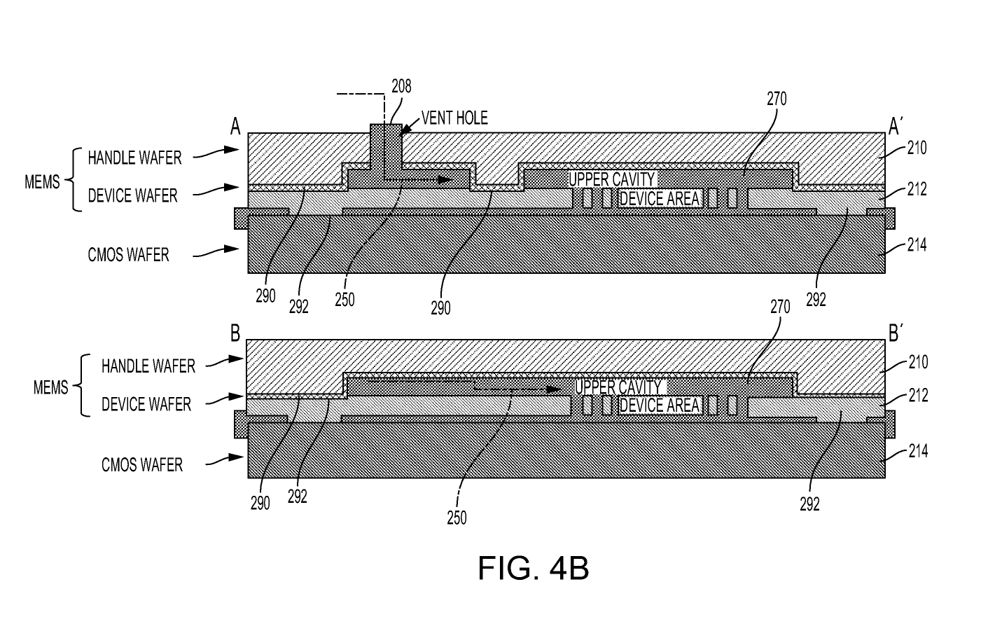

FIGS. 4A and 4B are diagrams that depict a second method for providing a channel through a MEMS device 200′. FIG. 4A illustrates a top view of MEMS device 200′. FIG. 4B illustrates a side view of the MEMS device 200′ which shows a MEMS substrate including handle wafer 210 and device layer 212 coupled to a CMOS substrate 214 and cross-sections A-A′ and B-B′ shown in FIG. 4A. FIG. 4B illustrates that a fusion oxide layer 290 is removed between the handle wafer 212 and the device wafer 212. Referring to the cross section B-B′ the channel 250 is provided through the area formerly occupied by the fusion oxide layer 290 to the upper cavity 270.

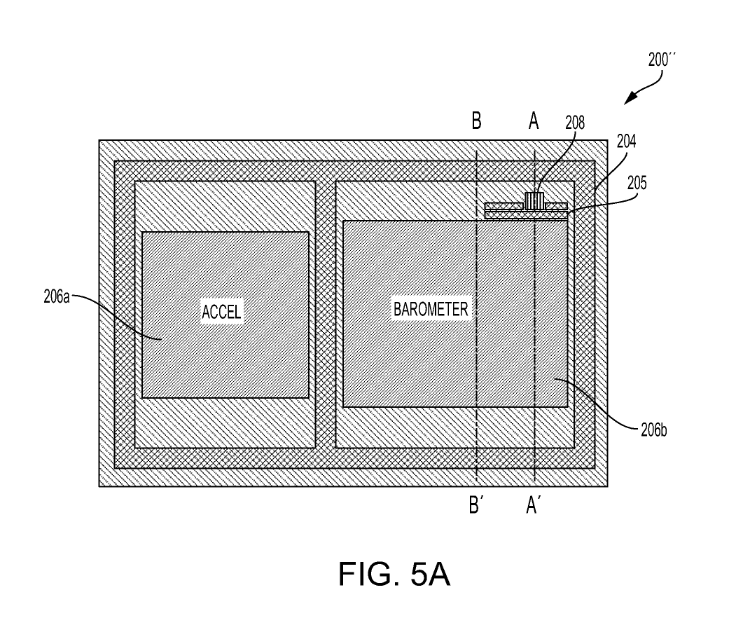

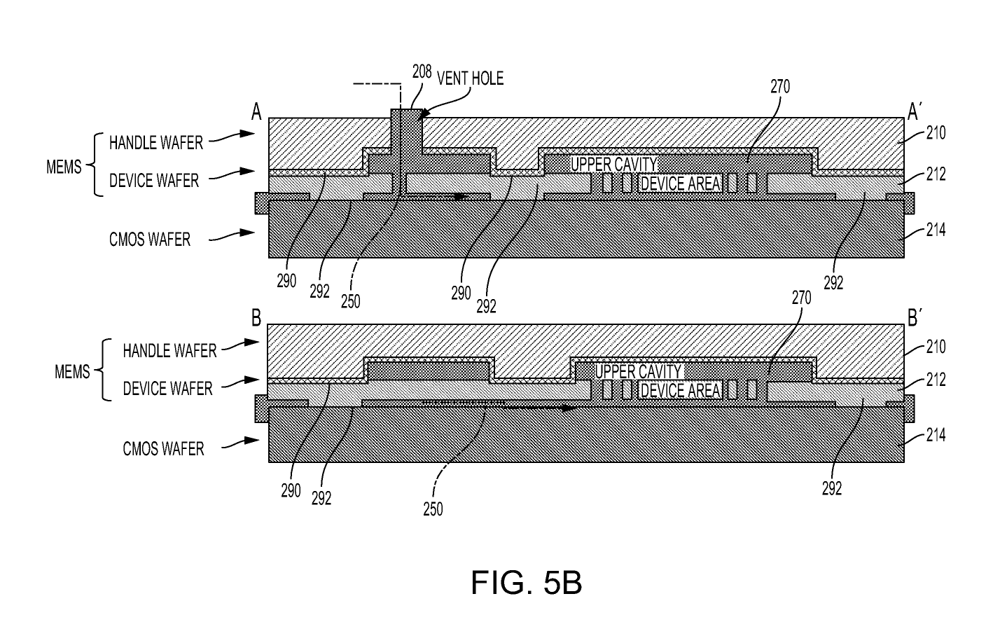

FIGS. 5A and 5B are diagrams that depict a third method for providing a channel through a MEMS device 200″. FIG. 5A illustrates a top view of MEMS device 200″. FIG. 5B illustrates a side view of the MEMS device 200″ which shows a MEMS substrate including handle wafer 210 and device layer 212 coupled to a CMOS substrate 214 and cross-sections A-A′ and B-B′ shown in FIG. 5A. FIG. 5B illustrates that an opening is provided through a standoff 292. Referring to the cross section B-B′ the channel 250 is provided through the area between the device wafer 212 and the device wafer 214.

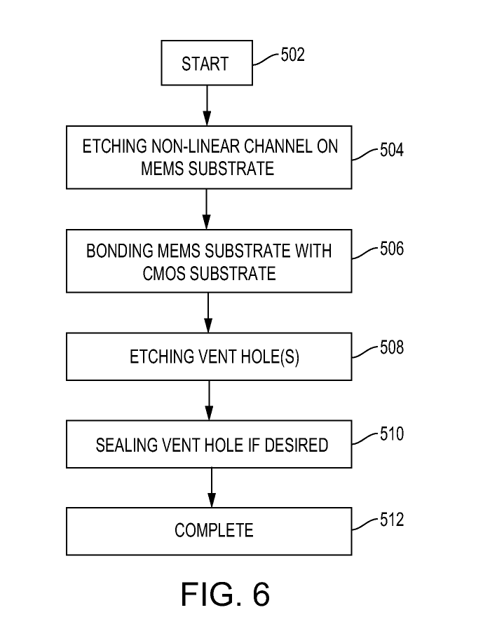

FIG. 6 sets forth a flowchart 500 of the method of manufacture of a MEMS device in accordance with one or more embodiments. In an embodiment, after starting, via step 502, a nonlinear channel is etched on a MEMS substrate, via step 504. In embodiments, the nonlinear channel could be etched ion either the handle wafer or the device wafer. Thereafter the MEMS substrate is bonded to a base substrate, via step 506. In embodiments, the bond may be a eutectic bond (e.g., AlGe, CuSn, AuSi), a fusion bond, compression, thermocompression, or an adhesive bond (e.g., glue, solder, anodic bonding, glass frit). Next one or more vent holes are etched into the MEMS device, via step 508. I

In a preferred embodiment, the method includes the etching of the one or more vent holes being performed through a first side of a handle wafer layer of the MEMS device substrate, thereby allowing air to flow into at least one of the plurality of cavities. In a further preferred embodiment, the method provides for the etching of the non-linear pathway being performed through a second side of a handle wafer layer of the MEMS device substrate, thereby allowing pressure to equalize as between at least one of the one or more vent holes and the MEMS device area. It will be appreciated that the etching processes may be performed serially or simultaneously without a preference as to order. It will be further appreciated that the determination of a pattern for the pathway of the channel to be configured to be non-linear as between the one or more vent holes and the device area may be determined by analysis, computer simulation, or other analytical process prior to etching.

From FIG. 6, the method further provides for sealing the one or more vent holes once a pressure of a first cavity of the plurality of cavities is set at a predetermined pressure, via step 510 if desired. The predetermined pressure may be preferably atmospheric pressure though the invention is not so limited. The method also provides for sealing the one or more vent holes once a pressure is equalized as between the at least one of the one or more vent holes and the MEMS device area. In an embodiment, the sealing step is performed by seal material such as solder material film (SMF) and the etching of the non-linear pathway is performed by UCAV etching, though the invention is not so limited. At step 512, the MEMS device of the present invention is complete.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the present invention.

What is claimed is:

1. A MEMS device comprising:
a MEMS substrate; the MEMS device substrate comprises: a MEMS device area; a seal ring for dividing the MEMS device area into a plurality of cavities, wherein at least one of the plurality of cavities includes one or more vent holes; and a channel between the one or more vent holes and the MEMS device area; wherein the channel minimizes particles entering the MEMS device area directly; and
a base substrate coupled to the MEMS substrate.

2. The MEMS device of claim 1, wherein the channel includes one or more barriers.

3. The MEMS device of claim 1, wherein the channel includes a pathway having one or more barriers, wherein the pathway is non-linear between the device area and the one or more vent holes.

4. The MEMS device of claim 1, wherein a size of the one or more vent holes is in a range between 15 um to 150 um.

5. The MEMS device of claim 1, wherein a dimensional opening of the one or more vent holes is in a range of approximately between 15 um to 150 um.

6. The MEMS device of claim 1, wherein a width of the channel is in a range between 0.2 um to 15 um.

7. The MEMS device of claim 1, wherein the base substrate comprises a CMOS substrate with an electronic circuit.

8. The MEMS device of claim 7, wherein at least one first conductive pad on the MEMS substrate is coupled to at least one second conductive pad on the CMOS substrate via a eutectic bond.

9. The MEMS device of claim 8, wherein the MEMS substrate includes at least one standoff thereon and wherein the at least one first conductive pad is coupled to the at least one standoff.

10. The MEMS device of claim 1, wherein the channel between the one or more vent holes is configured to provide venting from the MEMS device area to the one or more vent holes indirectly.

11. The MEMS device of claim 10, wherein a pathway of the channel between the MEMS device area and the one or more vent holes is disposed within the barrier.

12. The MEMS device of claim 11, wherein the pathway is vented through at least one standoff included on the MEMS substrate.

13. The MEMS device of claim 10, wherein the one or more vent holes are sealed whereby the MEMS device area is at a predetermined pressure.

14. A method for manufacturing a MEMS device, comprising:
providing a MEMS device substrate, wherein the MEMS device substrate includes a MEMS device area and a seal ring for dividing the MEMS device area into a plurality of cavities;
etching one or more vent holes to be configured with at least one of the plurality of cavities;
etching a channel between the one or more vent holes and the MEMS device area, wherein the channel minimizes particles entering the MEMS device area directly; and
bonding a base substrate to the MEMS device substrate.

15. The method of claim 14, wherein the channel includes one or more barriers.

16. The method of claim 14, wherein the channel includes a pathway having one or more barriers, wherein the pathway is non-linear between the device area and the one or more vent holes.

17. The method of claim 14, wherein the base substrate comprises a CMOS substrate with an electronic circuit.

18. The method of claim 17, wherein at least one first conductive pad on the MEMS substrate is coupled to at least one second conductive pad on the CMOS substrate via a eutectic bond.

19. The method of claim 18, wherein the MEMS substrate includes at least one standoff thereon and wherein the at least one first conductive pad is coupled to the at least one standoff.

20. The method of claim 14, wherein a non-linear pathway through the channel is etched through an upper cavity in the MEMS substrate.

21. The method of claim 19, wherein a non-linear pathway through the channel is provided through the at least one standoff.

22. The method of claim 14, further comprising sealing the one or more vent holes once a pressure of a first cavity of the plurality of cavities is set at a predetermined pressure.

23. The method of claim 22, wherein the sealing step is performed by SMF coating.

24. The method of claim 17, wherein the etching of the non-linear pathway is performed by UCAV etching.
